(19) United States
(12) Patent Application Publication
(10) Pub. No.: US 2010/0072608 A1
(43) Pub. Date: Mar. 25, 2010

(54) Semiconductor device

(75) Inventor: Shigekazu Kataoka, Aichi-gun (JP)

Correspondence Address: OLIFF & BERRIDGE, PLC, P.O. BOX 320850, ALEXANDRIA, VA, 22320-4850, US

(73) Assignee: DENSO CORPORATION, KARIYA-CITY (JP)

(21) Appl. No.: 12/585,664

(22) Filed: Sep. 21, 2009

(30) Foreign Application Priority Data
Sep. 24, 2008 (JP) 2008-243879

(51) Int. Cl. H01L 23/48; H01L 23/06; H01L 23/28

(52) U.S. Cl. 257/693; 257/708; 257/787; 257/E23.01; 257/E23.191; 257/E23.116

(57) ABSTRACT

A semiconductor device is disclosed which includes a metal base, a semiconductor chip, a lead, and a sealant. The semiconductor chip has an opposite pair of first and second electrode surfaces and a side surface. The semiconductor chip is fixed on the metal base with the first electrode surface solder-connected to the metal base. The lead is solder-connected to the second electrode surface of the semiconductor chip. The sealant seals, at least, the side surface of the semiconductor chip and solders connecting the metal base, the semiconductor chip, and the lead. Further, the lead has a small-cross-section portion which has a smaller cross-sectional area perpendicular to the longitudinal direction of the lead than other portions of the lead adjacent to the small-cross-section portion.

### CROSS-REFERENCE TO RELATED APPLICATION

This application is based on and claims priority from Japanese Patent Application No. 2008-243879, filed on Sep. 24, 2008, the content of which is hereby incorporated by reference in its entirety into this application.

### BACKGROUND OF THE INVENTION

1. Technical Field of the Invention

The present invention relates to semiconductor devices for use in, for example, rectifiers of automotive alternators.

2. Description of the Related Art

An automotive alternator for a motor vehicle, such as a passenger car or a truck, is generally driven by an engine of the vehicle to generate electric power, thereby charging a battery of the vehicle and powering various electrical devices provided on the vehicle. Moreover, to keep or improve market competitiveness, it is necessary for the alternator to have high durability while being compact, able to output high power, and inexpensive.

For example, a rectifying element of a rectifier included in the alternator is generally made up of a semiconductor device that includes a semiconductor diode chip. During operation of the alternator, a large current flows through the rectifying element, causing the rectifying element to generate heat. Therefore, the rectifying element is generally mounted to a heat sink of the rectifier by, for example, soldering or press-fitting, so as to effectively dissipate the heat generated by the semiconductor diode chip.

More specifically, the rectifying element is generally configured to include: a cylindrical metal base having a recess formed in an axial end surface thereof; the semiconductor diode chip that is received in the recess of the metal base and solder-connected to the bottom surface of the recess, and a lead that has one end solder-connected to the semiconductor diode chip and the other end extending outside of the recess of the metal base. Further, a sealant, which is made of, for example, a silicone rubber or a resin, is filled in the recess of the metal base to seal the semiconductor diode chip. In addition, to extend the thermal fatigue life of solders connecting the lead, the semiconductor diode chip, and the metal base, a buffer, which is made of, for example, CIC (Cu—In—Cn), is interposed between the semiconductor diode chip and the bottom surface of the recess of the metal base to relieve thermal stresses on the solders. During operation of the alternator, the heat generated by the semiconductor diode chip is dissipated by transferring it from the chip to the heat sink via the metal base and by exposing the rectifying element directly to the cooling air flow created by a cooling fan of the alternator.

Moreover, since the thermal fatigue life of the solders is shortened with increase in the operating temperature of the rectifying element, it is preferable to increase the flow rate of the cooling fan to more effectively cool the rectifying element. However, increasing the flow rate of the cooling fan also causes some problems, such as increasing the noise generated by the cooling fan.

Japanese Patent First Publications No. H9-289270 and No. H7-161877 disclose a method of extending the thermal fatigue life of the solders. More specifically, according to the method, the sealant for sealing the semiconductor diode chip is made of a resin containing a filler material, so as to reduce the thermal stresses on the solders.

However, with the above method, since the resin is less flexible than a silicone rubber, the sealant may be peeled off from the lead due to the cyclic change in operating temperate of the rectifying element.

Furthermore, when the alternator is reversely connected to the battery by mistake and thus an overcurrent flows through the rectifying element, the components of the rectifying element may be overheated and thereby be damaged.

### SUMMARY OF THE INVENTION

According to the present invention, there is provided a semiconductor device which includes a metal base, a semiconductor chip, a lead, and a sealant. The semiconductor chip has an opposite pair of first and second electrode surfaces and a side surface. The semiconductor chip is fixed on the metal base with the first electrode surface solder-connected to the metal base. The lead is solder-connected to the second electrode surface of the semiconductor chip. The sealant seals, at least, the side surface of the semiconductor chip and solders connecting the metal base, the semiconductor chip, and the lead. Further, in the semiconductor device, the lead has a small-cross-section portion which has a smaller cross-sectional area perpendicular to the longitudinal direction of the lead than other portions of the lead adjacent to the small-cross-section portion.

With the above configuration, when an overcurrent accidentally flows through the semiconductor device, the small-cross-section portion of the lead will be melted to break the lead. Consequently, it becomes possible to prevent the other components of the semiconductor device than the lead from being damaged by overheating. As a result, the reliability of the semiconductor device can be improved.

Moreover, the small-cross-section portion of the lead may be embedded in the sealant. Further, the sealant may be preferably made of a thermosetting resin. In this case, the recess formed between the small-cross-section portion and the adjacent portions would be completely filled with the sealant. Consequently, it would be possible to more reliably prevent the sealant from being peeled off from the lead due to the cyclic change in operating temperature of the semiconductor device. As a result, it would be possible to more securely hold the lead in the semiconductor device.

Alternatively, the small-cross-section portion of the lead may be located outside of the sealant. In this case, it would be possible to easily check the state of the small-cross-section portion.

It is preferable that the cross-sectional area of the small-cross-section portion of the lead be less than or equal to half those of the adjacent portions. In this case, it would be possible for the small-cross-section portion to generate more heat and thereby be more easily melted to break the lead. Moreover, it would become more difficult for the sealant to be peeled off from the lead.

It is also preferable that the small-cross-section portion of the lead have a longitudinal section that has an opposite pair of arcuate sides lying on the side surface of the lead. In this case, it would be possible to prevent stress concentration from occurring in the lead, thereby more reliably preventing the sealant from peeing off from the lead.

It is also preferable that the small-cross-section portion of the lead have a side surface that includes at least one flat section. In this case, it would be possible to more easily form the small-cross-section portion by, for example, shaving.

The metal base may be cylindrical in shape and have a recess formed in an axial end surface thereof. The semiconductor chip may be received in the recess of the metal base. The sealant may be applied to completely infill the recess of the metal base. In this case, it would be possible for the sealant to more reliably seal the semiconductor chip and the solders connecting the metal base, the semiconductor chip, and the lead. In addition, the semiconductor chip could be more securely held in the semiconductor device.

The semiconductor device may be a rectifying element employed in a rectifier of an automotive alternator. In this case, when the alternator is reversely connected to a battery of the vehicle by mistake and thus an overcurrent flows through the rectifying element, the components of the rectifying element other than the lead would be prevented from being damaged by overheating. As a result, the reliability of the rectifying element and thus that of the entire automotive alternator could be improved.

### BRIEF DESCRIPTION OF THE DRAWINGS

The present invention will be understood more fully from the detailed description given hereinafter and from the accompanying drawings of one preferred embodiment of the invention, which, however, should not be taken to limit the invention to the specific embodiment but are for the purpose of explanation and understanding only.

In the accompanying drawings:

FIG. 1 is a partially cross-sectional view of an automotive alternator according to the preferred embodiment of the invention;

FIG. 2 is a plan view of a rectifier of the alternator;

FIG. 3 is a schematic cross-sectional view of a rectifying element of the rectifier;

FIG. 4 is a graphical representation illustrating the relationship between a parameter S1/S and the amount of heat generated by a small-cross-section portion of a lead of the rectifying element;

FIG. 5 is a schematic cross-sectional view illustrating a modification of the rectifying element;

FIG. 6 is a schematic cross-sectional view illustrating another modification of the rectifying element; and

FIGS. 7A and 7B are schematic cross-sectional views illustrating yet other modifications of the rectifying element.

### DESCRIPTION OF PREFERRED EMBODIMENT

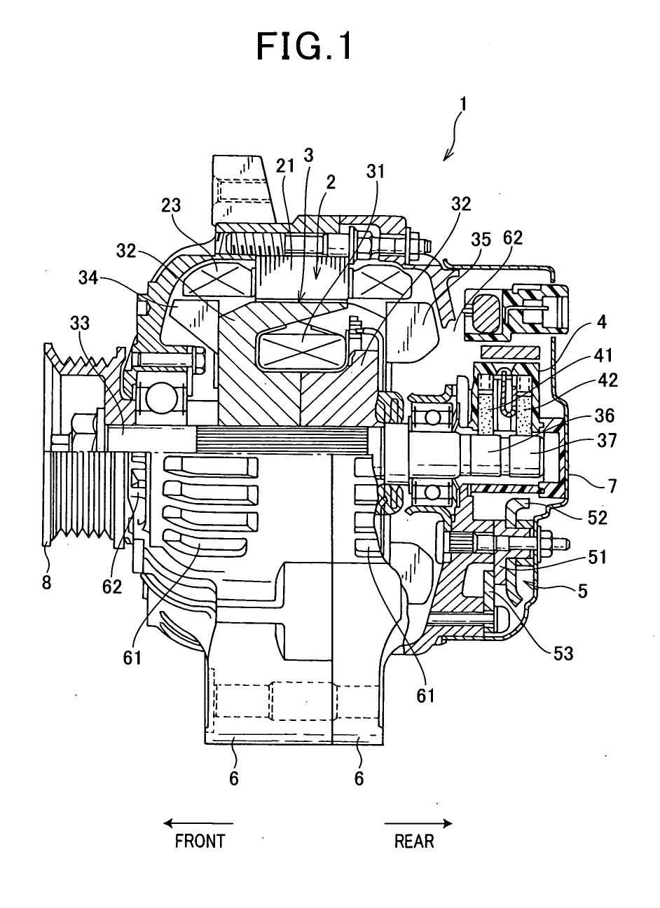

FIG. 1 shows the overall configuration of an automotive alternator 1 according to a preferred embodiment of the invention. The alternator 1 is designed to be used in a motor vehicle, such as a passenger car or a truck.

As shown in FIG. 1, the alternator 1 includes a stator 2, a rotor 3, a brush assembly 4, a rectifier 5, a frame 6, a protective cover 7, and a pulley 8.

The stator 2 includes a hollow cylindrical stator core 21 and a three-phase stator coil 23 wound around the stator core 21.

The rotor 3 is disposed radially inside of the stator core 2. The rotor 3 includes a filed coil 31, a pair of Lundell-type pole cores 32, a rotating shaft 33, and cooling fans 34 and 35. The field coil 31 is formed into a hollow cylindrical shape. Each of the pole cores 32 includes a boss portion and a plurality of (e.g., six) claw poles. The boss portions of the pole cores 32 are serration-fitted on the rotating shaft 33 in contact with each other; they also have the field coil 31 fitted thereon. The claw poles of the front-side pole core 32 are interleaved with those of the rear-side pole core 32. The cooling fan 34 is fixed to an axial end surface of the front-side pole core 32 by, for example, welding. The cooling fan 34 is a mixed flow fan which sucks cooling air from the front side and discharges the same in both the axial and radial direction of the rotating shaft 33. On the other hand, the cooling fan 35 is fixed to an axial end surface of the rear-side pole core 32 by, for example, welding. The cooling fan 35 is a centrifugal fan which sucks cooling air from the rear side and discharges the same in the radial direction of the rotating shaft 33.

The brush assembly 4 is provided to supply field current to the field coil 31 during rotation of the rotor 3. The brush assembly 4 includes a pair of brushes 41 and 42 that are respectively spring-loaded on a pair of slip rings 36 and 37 formed on a rear end portion of the rotating shaft 33.

The rectifier 5 is configured to full-wave rectify three-phase AC power output from the three-phase stator coil 23 of the stator 2 into DC power. The detailed configuration of the rectifier 5 will be described later.

The frame 6 accommodates therein both the stator 2 and the rotor 3. The frame 6 also rotatably supports the rotating shaft 33 of the rotor 3, and fixedly holds the stator core 21 of the stator 2 with a predetermined radial gap between the stator core 21 and the pole cores 32 of the rotor 3. Moreover, the frame 6 has a plurality of cooling air discharge holes 61 and a plurality of cooling air suction holes 62. The cooling air discharge holes 61 are formed through the side wall of the frame 6 to face those portions of the stator coil 23 which axially protrude from the axial end surfaces of the stator core 21. The cooling air suction holes 62 are formed through the front and rear end walls of the frame 6 to face the pole cores 32 of the rotor 3.

The protective cover 7 is so fixed to the rear end wall of the frame 6 that it covers those components of the alternator 1 which are located outside of the frame 6 (e.g., the brush assembly 4 and the rectifier 5), thereby protecting them from foreign matter.

The pulley 8 is mounted on a front end portion of the rotating shaft 33 which protrudes outside of the frame 6.

In operation of the alternator 1, torque generated by an engine of the vehicle is transmitted to the pulley 8 via a belt (not shown), thereby rotating the rotor 3 in a predetermined direction. Further, during the rotation of the rotor 3, the field current is supplied to the field coil 31, thereby magnetizing the claw poles of the pole cores 32 to create a rotating magnetic field. The rotating magnetic field induces the three-phase AC power in the stator coil 23 of the stator 2. Then, the three-phase AC power is output from the stator coil 23 and rectified by the rectifier 5 into the DC power. Part of the DC power is used as the field current to energize the field coil 31 of the rotor 3, while the remaining part is output from the alternator 1 to charge a battery of the vehicle and power various electrical devices provided on the vehicle.

After having described the overall configuration of the automotive alternator 1, the detailed configuration of the rectifier 5 will be described hereinafter.

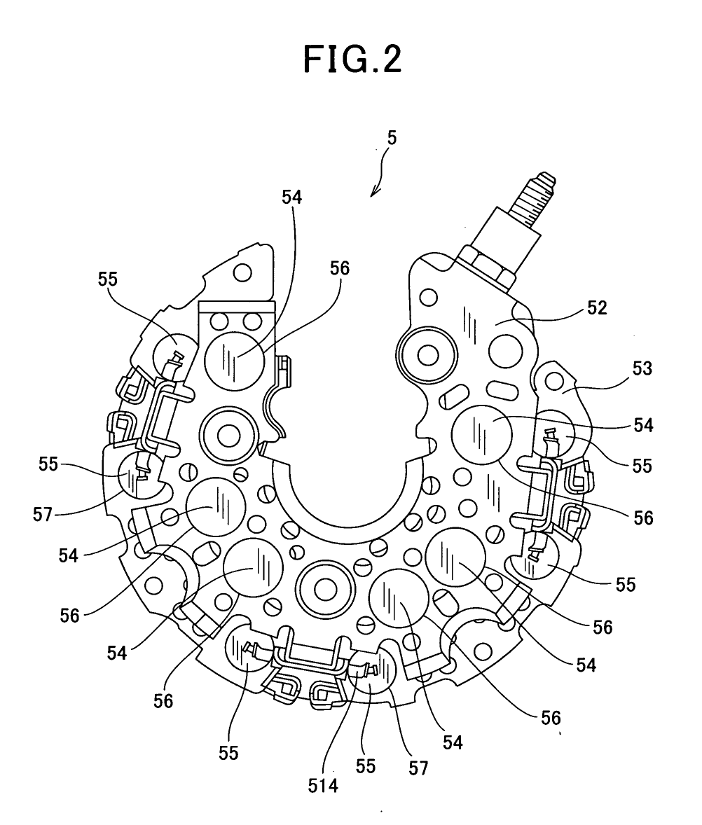

Referring to FIGS. 1 and 2, the rectifier 5 includes a terminal block 51, a positive (or positive-side) heat sink 52, a negative (or negative-side) heat sink 53, a plurality of (e.g., six) positive rectifying elements 54, and a plurality of (e.g., six) negative rectifying elements 55.

The terminal block 51 is made of, for example, a resin. The terminal block 51 is interposed between the positive and negative heat sinks 52 and 53 to electrically insulate them from each other. The terminal block 51 has electrical conductors 514 insert-molded therein. The electrical conductors 514 electrically connect the three-phase stator coil 23 of the stator 2 to the positive rectifying elements 54 and the negative rectifying elements 55.

Each of the positive and negative heat sinks 52 and 53 is made of a metal plate. The positive and negative heat sinks 52 and 53 are apart from each other in the axial direction of the rotating shaft 33 and disposed around the rotating shaft 33 such that they overlap each other in the axial direction of the rotating shaft 33.

The positive rectifying elements 54 and the negative rectifying elements 54 are electrically connected together, via the electrical conductors 514 provided in the terminal block 51, to full-wave rectify the three-phase AC power output from the three-phase stator coil 23 into the DC power. Each of the positive rectifying elements 54 is press-fitted in a corresponding one of a plurality of (e.g., six) fitting holes 56 formed in the positive heat sink 52. On the other hand, each of the negative rectifying elements 54 is press-fitted in a corresponding one of a plurality of (e.g., six) fitting holes 57 formed in the negative heat sink 53. In addition, in the present embodiment, each of the fitting holes 56 and 57 is a through-hole.

It should be noted that in the present embodiment, all of the positive and negative rectifying elements 54 and 55 are formed as semiconductor devices that have the same configuration. Therefore, for the sake of simplicity, only the configuration of one of the positive rectifying elements 54 will be described below.

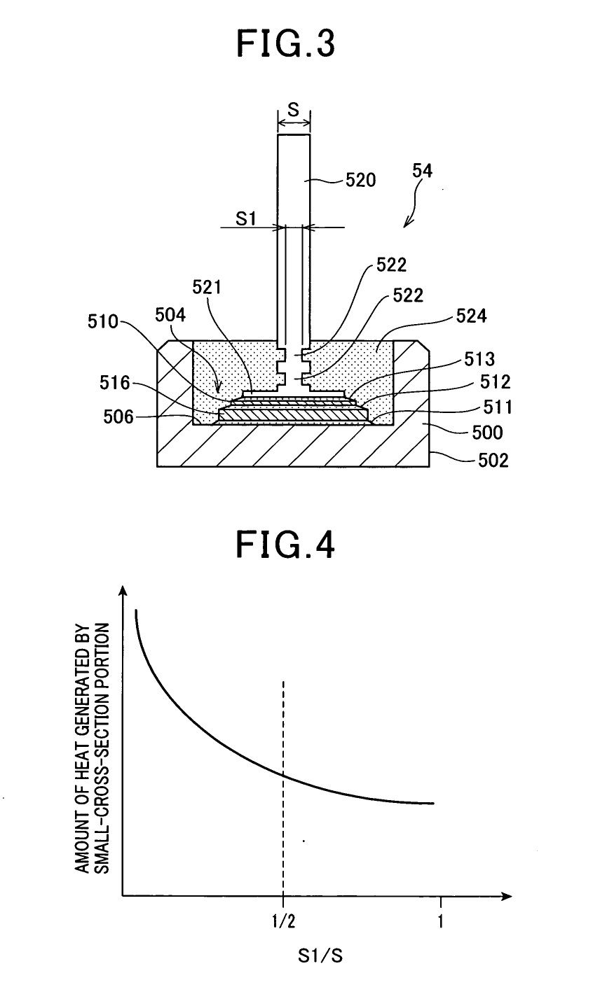

Referring to FIG. 3, the positive rectifying element 54 includes a cylindrical metal base 500, a semiconductor diode chip 510, a buffer plate 516, and a lead 520.

The cylindrical metal base 500 has knurls 502 formed on the side surface of the metal base 500 and a recess 504 formed in one axial end surface of the meal base 500. In mounting the positive rectifying element 54 to the positive heat sink 52, the knurled side surface of the metal base 500 is press-fitted to the inner surface of the positive heat sink 52 which defines the corresponding fitting hole 56. The bottom surface of the recess 504 (i.e., the inner surface of the metal base 500 which defines the bottom of the recess 504) serves as a joining surface 506 of the metal base 500.

The semiconductor diode chip 510 has a cylindrical shape, the axial end surfaces of which respectively make up two opposite electrode surfaces of the chip 510. The buffer plate 516 has a circular cross section. The lead 520 is made of a circular metal wire and has a disc-shaped head portion 521 formed at one end of the lead 520.

In manufacturing the positive rectifying element 54, the buffer plate 516 is first disposed on and soldered to the joining surface 506 of the metal base 500, forming a solder layer 511 between the lower major surface of the buffer plate 516 and the joining surface 506 of the metal base 500. Then, the semiconductor diode chip 510 is disposed on and soldered to the buffer plate 516, forming a solder layer 512 between the lower electrode surface of the chip 510 and the upper major surface of the buffer plate 516. Further, the head portion 521 of the lead 520 is disposed on and soldered to the semiconductor diode chip 510, forming a solder layer 513 between the end surface of the head portion 521 and the upper electrode surface of the chip 510. Thereafter, a sealant 524, which is made of a thermosetting resin containing a filler material, is filled in the recess 504 of the metal base 500 to seal the side surface of the semiconductor diode chip 510 and all of the exposed portions of the solder layers 511, 512, and 513. In addition, in the present embodiment, the sealant 524 is applied to completely infill the recess 504 of the metal base 500.

According to the present embodiment, the lead 520 is configured to include two small-cross-section portions 522 each of which has a smaller cross-sectional area perpendicular to the longitudinal direction of the lead 520 than other portions of the lead 520 adjacent thereto. More specifically, in the present embodiment, each of the small-cross-section portions 522 has a smaller diameter than the adjacent portions. Further, the cross-sectional area S1 of each of the small-cross-section portions 522 is set to be less than or equal to half the cross-sectional areas S of the adjacent portions (i.e., S1/S≦1/2). Furthermore, each of the small-cross-section portions 522 is embedded in the sealant 524 so that the recess formed between the small-cross-section portion 522 and the adjacent portions is completely filled with the sealant 524.

FIG. 4 illustrates the relationship between the amount of heat generated by each of the small-cross-section portions 522 and the ratio S1/S.

It can be seen from FIG. 4 that the amount of heat generated by each of the small-cross-section portions 522 rapidly increases when the ratio S1/S drops below 1/2.

In general, the diameter of the lead 520 is in the range of 1 to 2 mm, and the amplitude of the current flowing through the lead 520 in a normal operating condition of the alternator 1 is several tens of Amperes. However, when the alternator 1 is reversely connected to the battery of the vehicle by mistake, the amplitude of the current flowing through the lead 520 may become several hundreds of Amperes. In this case, with the ratio S1/S being not greater than 1/2, each of the small-cross-section portions 522 would generate a huge amount of heat, thereby being melted to break the lead 520.

The above-described semiconductor device (i.e., the positive rectifying element 54) according to the present embodiment has the following advantages.

In the positive rectifying element 54, the lead 520 is configured to include the small-cross-section portions 522 each of which has a smaller cross-sectional area perpendicular to the longitudinal direction of the lead 520 than other portions of the lead 520 adjacent thereto.

With the above configuration, when an overcurrent accidentally flows through the positive rectifying element 54, the small-cross-section portions 522 of the lead 520 will be melted to break the lead 520. Consequently, it becomes possible to prevent the other components of the positive rectifying element 54 than the lead 520 from being overheated to be damaged. As a result, the reliability of the positive rectifying element 54 and thus that of the entire rectifier 5 can be improved.

Moreover, in the present embodiment, each of the small-cross-section portions 522 is embedded in the sealant 524 so that the recess formed between the small-cross-section portion 522 and the adjacent portions is completely filled with the sealant 524.

Consequently, it becomes possible to more reliably prevent the sealant 524 from being peeled off from the lead 524 due to the cyclic change in operating temperature of the positive rectifying element 54. As a result, it becomes possible to more securely hold the lead 520 in the rectifier 5.

In the present embodiment, there is specified the relationship of S1/S≦1/2, where S1 represents the cross-sectional area S1 of each of the small-cross-section portions 522, and S represents the cross-sectional areas of the adjacent portions.

By specifying the above relationship, it becomes possible for each of the small-cross-section portions 522 to generate more heat and thereby be more easily melted to break the lead 520. Moreover, it becomes more difficult for the sealant 524 to be peeled off from the lead 524.

In the present embodiment, the sealant 524 is applied to completely infill the recess 504 of the metal base 500.

Consequently, it is possible for the sealant 524 to more reliably seal the semiconductor diode chip 510 and the solder layers 511, 512, and 513. In addition, the semiconductor diode chip 510 can be more securely held in the positive rectifying element 54.

While the above particular embodiment of the invention has been shown and described, it will be understood by those skilled in the art that various modifications, changes, and improvements may be made without departing from the spirit of the invention.

For example, in the previous embodiment, each of the small-cross-section portions 522 of the lead 520 has a circular cross section coaxial with those of the adjacent portions. However, each of the small-cross-section portions 522 may also have a circular cross section which is non-coaxial with those of the adjacent portions.

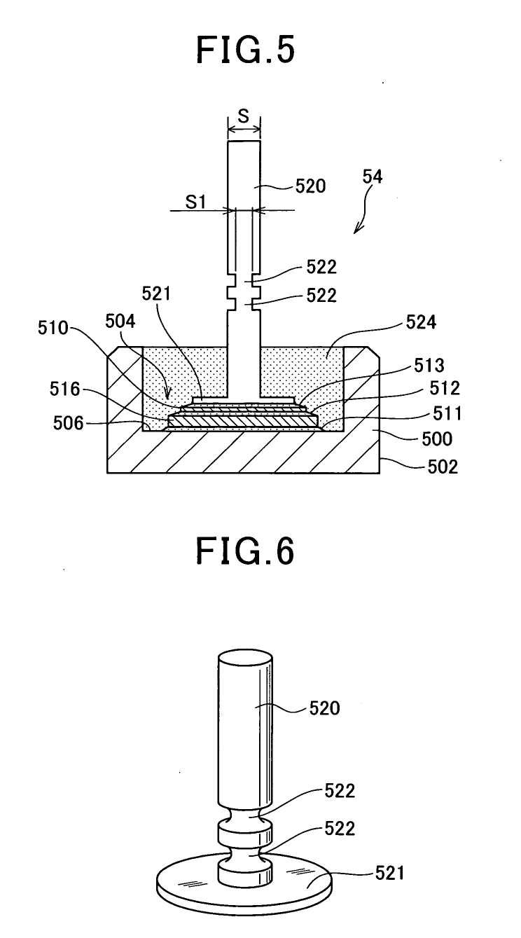

In the previous embodiment, both the small-cross-section portions 522 of the lead 520 are located inside of the recess 504 of the metal base 500 and thus completely embedded in the sealant 524. However, as shown in FIG. 5, both the small-cross-section portions 522 may also be located outside of the recess 504 and thus exposed from the sealant 524. In this case, at the expense of the capability of reliably preventing the sealant 524 from peeling off from the lead 520, it becomes possible to easily check the state of the small-cross-section portions 522 (more specifically, check whether or not the small-cross-section portion is melted).

In the previous embodiment, each of the small-cross-section portions 522 of the lead 520 has a longitudinal section that is rectangular in shape. However, as shown in FIG. 6, each of the small-cross-section portions 522 may also have a longitudinal section that has an opposite pair of arcuate sides lying on the side surface of the lead 520. In this case, it is possible to prevent stress concentration from occurring in the lead 520, thereby more reliably preventing the sealant 524 from peeing off from the lead 520.

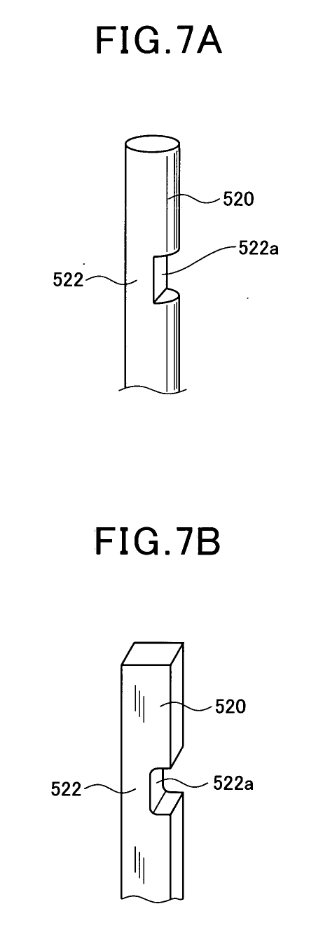

In the previous embodiment, each of the small-cross-section portions 522 of the lead 520 has a cylindrical side surface. However, as shown in FIGS. 7A and 7B, each of the small-cross-section portions 522 may also have a side surface that includes a flat section 522a. In this case, it is possible to easily form the small-cross-section portions 522 by, for example, shaving.

In the previous embodiment, the lead 520 is made of a circular metal wire. However, as shown in FIG. 7B, the lead 520 may also be made of a rectangular metal wire.

In the previous embodiment, the number of the small-cross-section portions 522 in the lead 520 is equal to two. However, the lead 520 may also include a different number of the small-cross-section portions 522, for example one or three.

In the previous embodiment, the buffer plate 516 is provided to prevent an excessive thermal stress from occurring between the metal base 500 and the semiconductor diode chip 510 due to the difference in thermal expansion coefficient therebetween. However, in terms of more effectively cooling the semiconductor diode chip 510, the buffer plate 516 may also be omitted from the configuration of the positive rectifying element 54.

In the previous embodiment, each of the fitting holes 56 and 57 formed in the positive and negative heat sinks 52 and 53 is a through-hole. However, each of the fitting holes 56 and 57 may also be a bottomed hole (or a recess) formed in one major surface of the positive heat sink 52 or the negative heat sink 53.

In the previous embodiment, the present invention is applied to the positive and negative rectifying elements 54 and 55 included in the rectifier 5 of the automotive alternator 1. However, the present invention can also be applied to other semiconductor devices.

What is claimed is:

1. A semiconductor device comprising:
a metal base;
a semiconductor chip having an opposite pair of first and second electrode surfaces and a side surface, the semiconductor chip being fixed on the metal base with the first electrode surface solder-connected to the metal base;
a lead that is solder-connected to the second electrode surface of the semiconductor chip; and
a sealant that seals, at least, the side surface of the semiconductor chip and solders connecting the metal base, the semiconductor chip, and the lead,
wherein
the lead has a small-cross-section portion which has a smaller cross-sectional area perpendicular to a longitudinal direction of the lead than other portions of the lead adjacent to the small-cross-section portion.

2. The semiconductor device as set forth in claim 1, wherein the small-cross-section portion of the lead is embedded in the sealant.

3. The semiconductor device as set forth in claim 2, wherein the sealant is made of a thermosetting resin.

4. The semiconductor device as set forth in claim 1, wherein the small-cross-section portion of the lead is located outside of the sealant.

5. The semiconductor device as set forth in claim 1, wherein the cross-sectional area of the small-cross-section portion of the lead is less than or equal to half those of the adjacent portions.

6. The semiconductor device as set forth in claim 1, wherein the small-cross-section portion of the lead has a longitudinal section that has an opposite pair of arcuate sides lying on the side surface of the lead.

7. The semiconductor device as set forth in claim 1, wherein the small-cross-section portion of the lead has a side surface that includes at least one flat section.

8. The semiconductor device as set forth in claim 1, wherein the metal base is cylindrical in shape and has a recess formed in an axial end surface thereof,
the semiconductor chip is received in the recess of the metal base, and
the sealant is applied to completely infill the recess of the metal base.

9. The semiconductor device as set forth in claim 1, wherein the semiconductor device is a rectifying element employed in a rectifier of an automotive alternator.
